(19) United States
(12) Patent Application Publication
(10) Pub. No.: US 2013/0201747 A1
(43) Pub. Date: Aug. 8, 2013

(54) PERMANENT SOLID STATE MEMORY USING CARBON-BASED OR METALLIC FUSES

(71) Applicant: Brigham Young University, Provo, UT (US)

(72) Inventors: Barry M. Lunt, Provo, UT (US); Matthew R. Linford, Provo, UT (US); Robert C. Davis, Provo, UT (US); Anthony Pearson, Vineyard, UT (US)

(73) Assignee: BRIGHAM YOUNG UNIVERSITY, Provo, UT (US)

(21) Appl. No.: 13/791,881

(22) Filed: Mar. 8, 2013

Related U.S. Application Data
(63) Continuation-in-part of application No. 13/016,936, filed on Jan. 28, 2011, now Pat. No. 8,467,215.
(60) Provisional application No. 61/634,939, filed on Mar. 8, 2012.
(60) Provisional application No. 61/634,940, filed on Mar. 8, 2012.

(51) Int. Cl. H01L 45/00; G11C 17/16

(52) U.S. Cl. CPC H01L 45/12; G11C 17/16; H01L 45/16
USPC 365/96; 257/2; 438/104

(57) ABSTRACT

A permanent solid state memory device is disclosed. Recording data in the permanent solid state memory device forms voids in a data layer between a first wire array and a second wire array. Wires of the first wire array extend transversely to wires in the second wire array. The material is made of a carbon allotrope such that when current is passed through the carbon allotrope, the carbon is quickly oxidized (burned) leaving a complete gap (void) where the fuse once was. One of the advantages of this method is that the fuse material is fully oxidized in the particular “neck region of the bowtie”, such that there is no material left over from which dendrites can grow. In other embodiments, the data layer is a metal or metal oxide selected from the following metals: Tungsten (W), Rhenium (Rh), Osmium (Os), Iridium (Ir), Molybdenum (Mo), Ruthenium (Ru), Rhodium (Rh), Chromium (Cr), and Manganese (Mn).

### CROSS REFERENCE TO RELATED APPLICATIONS

The present application is a continuation-in-part of U.S. patent application Ser. No. 13/016,936 filed on Jan. 28, 2011, which application claims the benefit of U.S. Provisional Application Ser. No. 61/299,927 filed on Jan. 29, 2010. The present application also claims the benefit of U.S. Provisional Application Ser. Nos. 61/634,939 and 61/634,940 filed on Mar. 8, 2012. All of the preceding patent applications are expressly incorporated herein by reference in their entireties.

### FIELD OF THE INVENTION

Embodiments of the present invention are directed generally to solid state memory devices, and more particularly to permanent solid state memory devices.

As noted above, this application is a continuation-in-part of U.S. patent application Ser. No. 13/016,936, which has been published as U.S. Patent Application Publication No. 2011/0188285 (hereinafter the “'285 publication”). The reader is presumed to be familiar with the disclosure of the '285 publication.

### DESCRIPTION OF RELATED ART

Solid state memory devices enable storage of data by programming patterns of data points between one or more pairs of transversely extending line arrays. Computer systems including transistors and other control elements are used to apply voltages to predetermined combinations of lines to program the pattern of data points. These control elements also apply voltages to the lines in order to read data from the solid state memory devices. Several patent applications disclose a variety of solid state memory devices.

U.S. Patent Publication 2007/0087543 to Piebe published Apr. 19, 2007 is directed to a solid state memory device having fuses configured to be disposed between wire arrays. Programming this type of solid state memory device entails “blowing” a predetermined pattern of these fuses that enables reading digital information from the device. There are many conventional solid state memory devices having fuses interconnected between wires at data points in a form similar to the teachings of this publication.

U.S. Patent Publication 2009/0180313 to Deweerd et al. published Jul. 16, 2009 discloses a solid state device having anti-fuses between lines and electrodes instead of fuses. These anti fuses actually become more conductive when programmed, and thus provide the digital data through making these changes at a predetermined pattern of data points during programming.

U.S. Patent Publication 2009/0168507 to Petti published Jul. 2, 2009 is directed to a solid state memory device having wires in one layer connected to wires in another layer by diodes and/or anti fuses. Programming this type of solid state memory device entails “soft blowing” a predetermined pattern of these anti fuses and/or switching a diode that places the predetermined pattern of data points in a data state for providing digital information that can be read from the device.

U.S. Patent Publication 2008/0158936 to Bertin et al. published Jul. 3, 2008 has a specialized memory cell that has nanotube fabric material between terminals that forms a data point. This data point changes in resistance when programmed. Thus, a pattern of data points can be programmed to provide digital data.

U.S. Patent Publication 2005/0122798 to Lung et al. published Jun. 9, 2005 discloses another specialized memory cell between bit lines and word lines. The memory cell in this case utilizes a mechanism that combines layers by heating distinct layers and causing a chemical reaction that forms an alloy. The alloy has a different resistance as compared with the layers in their uncombined state. Thus, data points are created by forming alloys at selected locations between respective bit lines and word lines. The resulting pattern of data points provides digital data.

Most conventional solid state memory devices utilize discrete fuses or anti fuses at the data points. Programming by “blowing” fuses is an explosive process that leads to dendrites in regions around the data marks, which eventually leads to data loss. Most solid state memory is reversible. For example, non-volatile flash memory is reversible through reprogramming when a user deletes or replaces data in the flash memory. Even if the user does not delete or replace the data, flash memory will eventually lose data through loss of charge at the data points, typically after 10-12 years. Many specialized solid state memory devices are very complex with multiple layers and/or multiple elements forming terminals, fuses, etc. Accordingly, there exists a need for a simple solid state memory device that is not susceptible to dendrites, reprogramming, or other potential data loss mechanisms. There is a need for a simple permanent solid state memory device that has one or more data layer(s) in which permanent structural changes provide permanent, irreversible data marks in a solid state memory.

### SUMMARY OF THE INVENTION

A permanent solid state memory device has a first wire array in a first layer and a second wire array in a second layer with a data layer disposed between the first layer and the second layer. Wires of the first wire array extend transversely to wires of the second wire array. The data layer spaces the first layer and the second layer at a distance approximately equal to a thickness of the data layer. The data layer is at least partially conductive such that a voltage applied between a selected first wire in the first array and a selected second wire in the second array creates a heating current through the data layer at a data point between the first wire and the second wire. The heating current causes a data layer material to oxidize (burn) and recede to form a permanent void. More specifically, a carbon allotrope material is used as a fuse that will be quickly oxidized (burned) when the current is applied, leaving a complete gap where the fuse once was. It should be noted that the carbon material may be fully consumed (oxidized) during the process. There may be some fuse material remaining, except in the specific area where it has been oxidized or moved away. This removal of material may inhibit dendrite formation (and inhibit dendrite-caused failure of the memory). In the case of carbon fuses, it is believed that the reason dendrites do not grow in the remaining fuse material is because carbon materials do not grow dendrites. Thus, carbon fuses are not likely to be subject to dendrite-caused failure.

The heating current is directed through a predetermined pattern of data points in order to record data as a pattern of permanent voids in the permanent solid state memory device. Transistors and other control elements are used to apply the voltages to predetermined combinations of wires in order to control where the heating currents are directed. These control elements apply the voltages to form the permanent voids at specific data points throughout the solid state memory device, which are subsequently readable as digital data.

In some embodiments, the data material that will be “blown” is a metal or a metallic oxide. More specifically, a metal, a metal alloy or a metallic oxide of the following elements may be used for the data layer: Tungsten (W), Rhenium (Rh), Osmium (Os), Iridium (Ir), Molybdenum (Mo), Ruthenium (Ru), Rhodium (Rh), Chromium (Cr), and Manganese (Mn). These materials, when burned via the application of a voltage, may be fully consumed in the immediate area where the heat reached the highest point, e.g., the “neck region of the bowtie”. (Some of the other fuse material may remain after the burning.) The burning may create a gap (void) between the wires. Again, this consumption of the data layer material removes the material that could possibly be used for dendrite formation, thereby inhibiting dendrite-caused failure of the memory device.

### DESCRIPTION OF THE FIGURES

The following figures form part of the present specification and are included to further demonstrate certain aspects of the present invention. The invention may be better understood by reference to one or more of these figures in combination with the detailed description of specific embodiments presented herein.

FIG. 1A shows an exploded perspective view of a permanent solid state memory device with transverse wire arrays on inner faces of each of a top substrate and a bottom substrate, and a data layer between the transverse wire arrays.

FIG. 1B shows an assembled perspective view of the permanent solid state memory device of FIG. 1A with the transverse wire arrays on inner faces of each of the top substrate and the bottom substrate, and a data layer between the transverse wire arrays.

FIG. 2A shows an exploded view of a stack of the permanent solid state devices of FIGS. 1A and 1B.

FIG. 2B shows a cross sectional view taken along line II-II of the stack of the permanent solid state devices of FIG. 2A in an assembled state in accordance with one embodiment.

FIG. 2C shows a cross sectional view taken along line II-II of the stack of the permanent solid state devices of FIG. 2A in an assembled state in accordance with another embodiment.

FIG. 3A shows a detailed cross sectional view taken along line III-III in FIG. 1B illustrating a data mark location in the data layer between a first wire supported on the first substrate and a second wire transverse to the first wire and supported on the second substrate prior to writing.

FIG. 3B shows a detailed cross sectional view taken along line III-III in FIG. 1B illustrating a data mark comprising a void in the data layer between the first wire supported on the first substrate and the second wire transverse to the first wire and supported on the second substrate after writing.

FIG. 4A shows a detailed cross sectional view taken along line III-III in FIG. 1B illustrating a data mark location in a carbon coated data layer between a first wire supported on the first substrate and a second wire transverse to the first wire and supported on the second substrate prior to writing.

FIG. 4B shows a detailed cross sectional view taken along line III-III in FIG. 1B illustrating a data mark comprising a void in the carbon coated data layer between the first wire supported on the first substrate and the second wire transverse to the first wire and supported on the second substrate after writing.

FIG. 5A shows a top view of a fuse and FIG. 5B shows the fuse (data material) in both an “unblown” and “blown” state, for comparison.

FIG. 6 is a flow diagram of a method of forming a fuse (data material) that is made of a carbon allotrope.

FIGS. 7A-7D are scanning electron microscope images of fuse devices of different sizes that incorporate carbon allotropes.

FIGS. 8A-8D are scanning electron microscope images of fuse devices which are 500 nm at their narrowest point, wherein the images of fuses incorporate carbon allotropes.

FIGS. 9A shows a top view of a fuse used between two gold contact pads.

FIG. 9B shows a graph of the programming temperature necessary to program the fuse of FIG. 9A.

FIG. 9C shows a sectional view taken along line c-c of FIG. 9A.

### DETAILED DESCRIPTION OF THE INVENTION

While compositions and methods are described in terms of “comprising” various components or steps (interpreted as meaning “including, but not limited to”), the compositions and methods can also “consist essentially of” or “consist of” the various components and steps, such terminology should be interpreted as defining essentially closed-member groups.

### Materials

As described above, there is a need for a simple permanent solid state memory device. Whereas conventional solid state memory devices are typically reversible and susceptible to data loss, there is a need for a solid state memory device that enables permanent recording of data. Fuse type solid state memory devices are programmed by explosive processes of “blowing” fuses between wires of respective wire arrays. Such blowing of fuses creates optimal conditions for dendrites to grow, by leaving material in the vicinity of the blown fuses that can serve as starting materials for the dendrites. Such dendrites may be worsened with exposure to high temperature or high humidity. Aside from the specific changes caused by recording to fuse type conventional solid state memory devices, fuse type and the other known solid state memory devices of the past are more complex, having terminals, specific fuse materials, antifuse materials, multiple layers, etc. Embodiments of the present invention, on the other hand, are simple in structure, permanent in duration of data storage, and physically irreversible.

In a simple form, a solid state memory device may include at least one first array of wires in a first layer and at least one second array of wires extending transversely relative to the first array of wires in a second layer. The first layer lies in a first plane, and the second layer lies in a second plane that is generally parallel to the first plane. In this embodiment, at least one data layer is disposed between the first layer and the second layer such that a voltage applied to a first wire in the first wire array and a second wire in the second wire array creates a current that heats the data layer at a location between the first wire and the second wire. The heating forms a data point that includes a void when data is written to the solid state memory device. The gap permanently changes the resistance of the fuse, thus programming the data. Where a fuse is intact a “1” is stored; where it has been destroyed, a “0” is stored (or vice versa).

Embodiments include the data layer formed from an allotrope of carbon such as, for example, single-wall nanotubes, multi-wall nanotubes, grapheme (single sheet or multiple sheets including multi-layer graphene), sputtered carbon, amorphous carbon, glassy carbon, or graphitic carbon. As deposited, the carbon allotrope has sufficient conductivity to program a 1 (an intact fuse). When current is passed through the carbon allotrope, the carbon is quickly oxidized (burned), leaving a complete gap where the fuse once was, and thus programming a 0 in that location. In some embodiments, the carbon (prior to the current being applied) may already be partially oxidized or contain hydrogen or impurities or dopants.

In further embodiments, the data layer may be made of a metal, metal alloy or metallic oxide of one or more of the following elements: Tungsten (W), Rhenium (Rh), Osmium (Os), Iridium (Ir), Molybdenum (Mo), Ruthenium (Ru), Rhodium (Rh), Chromium (Cr), and Manganese (Mn).

The data layer can further comprise at least one dopant. The dopant can be used to modulate or modify the thermal, resistive, optical, and stability profile of the data layer material.

The data layer can generally be any thickness. In one embodiment, the data layer has a thickness of about 3 nm to about 300 nm. A lower thickness limit can be about 2 nm. An upper thickness limit can be about 250 nm. Example thicknesses are about 2 nm, about 3 nm, about 4 nm, about 6 nm, about 8 nm, about 10 nm, about 12 nm, about 14 nm, about 16 nm, about 18 nm, about 20 nm, about 30 nm, about 40 nm, about 50 nm, about 60 nm, about 70 nm, about 80 nm, about 90 nm, about 100 nm, about 110 nm, about 120 nm, about 130 nm, about 140 nm, about 150 nm, about 160 nm, about 170 nm, about 80 nm, about 90 nm, about 200 nm, about 210 nm, about 220 nm, about 230 nm, about 240 nm, about 250 nm, about 260 nm, about 270 nm, about 280 nm, about 290 nm, about 300 nm and ranges between any two of these values. The data layer may have a thickness of any value within this range. For example, the thickness of the data layer may be approximately 15 nm.

In some embodiments, the first wire and the second wire have a maximum dimension taken along a cross section generally perpendicular to a lengthwise extension of the wire in which the maximum dimension is about 30 nm to about 5000 nm. The first wire and the second wire may have a cross sectional area generally perpendicular to a lengthwise extension of the wires of about 900 nm² (30 nm×30 nm−minimum processing dimension squared) to about 25,000,000 nm². In some cases, the first wire and the second wire may have a minimum dimension that is smaller than the minimum process dimension. This can occur when the wires are formed of a thinner height dimension than the process dimension. For example, one or both wires could be deposited to a 2 nm to 5 nm thickness while having the process dimension width of 30 nm. In these cases, the cross sectional area of the wire(s) may be from 60 nm² to 150 nm².

Embodiments may include the first layer having a first substrate and the first wire array supported on the first substrate. The second layer may include a second substrate and the second wire array supported on the second substrate. In these embodiments, the first substrate is bonded to the second substrate with the data layer disposed between the first substrate and the second substrate. In other embodiments, multiple data layers and multiple wire arrays are disposed on opposing sides of the multiple data layers, wherein the multiple data layers are in respective layers between respective wire arrays. The number of data layers may be two, three, four, five, six, seven, eight, or more data layers with substrates having wire arrays on each side of the data layers.

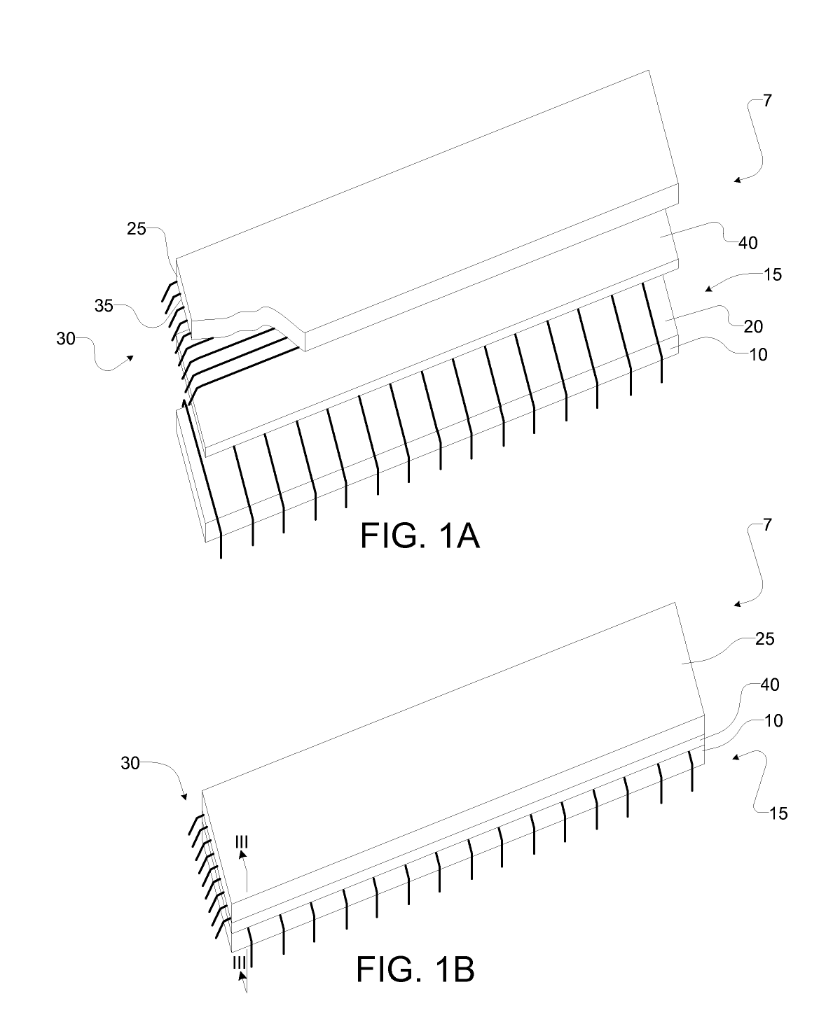

With particular reference to the figures, FIG. 1A shows an exploded perspective view of a permanent solid state memory device 7. A first substrate 10 has a first wire array 15 supported on an upper surface 20 of the first substrate. A second substrate 25 has a second wire array 30 supported on a lower surface 35 of the second substrate 25. The wires of the first wire array 15 extend transversely and overlie the wires of the second wire array 30. The substrates 10, 25 and the wire arrays 15, 30 are oriented such that the wire arrays are on inner faces of each of top and bottom substrates 25, 10 and a data layer 40 is located between the wire arrays 15, 30.

FIG. 1B shows an assembled perspective view of the permanent solid state memory device 7 with the transverse wire arrays 15, 30 on inner faces of each of top substrate 25 and the bottom substrate 10. As shown, the data layer 40 is sandwiched between the transverse wire arrays 15, 30. The assembled permanent solid state memory device 7 may be integrated with any number of control elements in a system configured to read from and write to the permanent solid state memory device 7. These elements may include transistors, drivers, amplifiers, row and column sense amplifiers, etc. that function to select and apply voltages to the wires in the wire arrays in the proper sequence for writing and/or reading. These elements and the resulting system may include conventional elements and combinations, and/or elements and combinations that have not yet been developed without limitation.

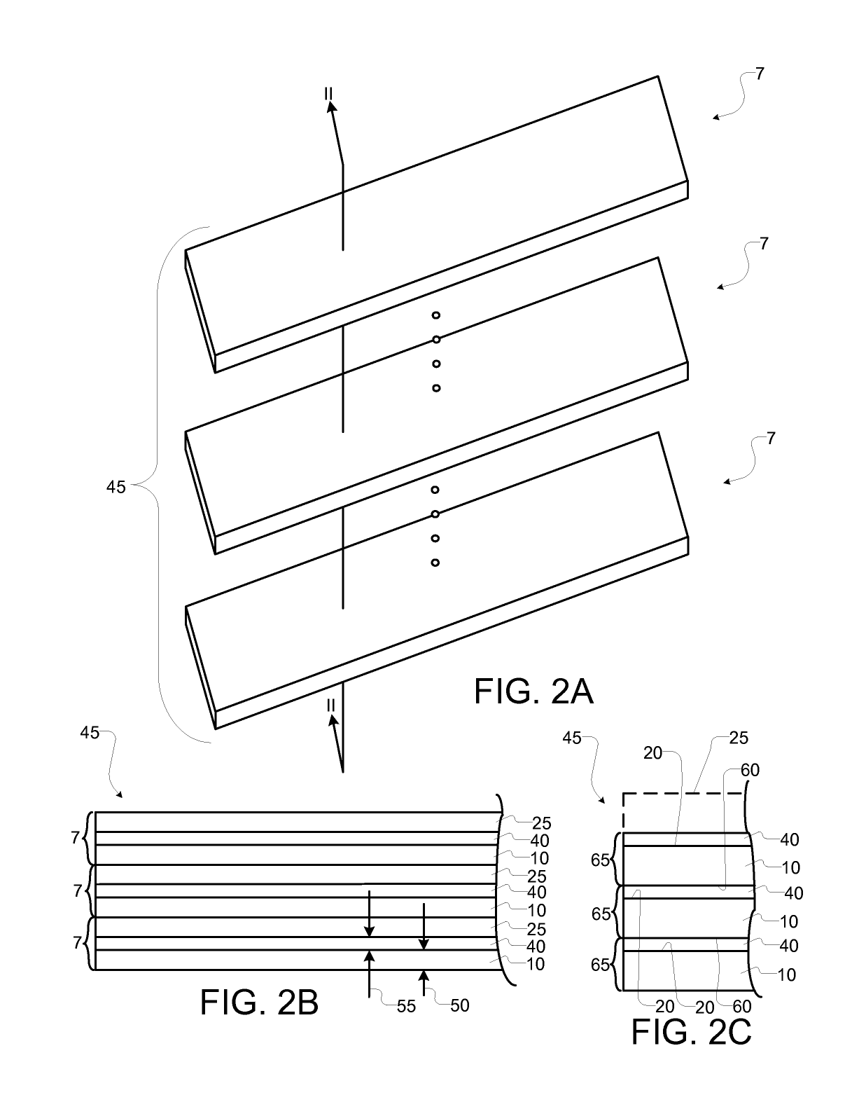

Advantageously, the solid state memory device 7 could be made into three-dimensional storage without a related increase in power dissipation. For example, FIG. 2A shows an exploded view of a stack 45 of the permanent solid state devices 7 of FIGS. 1A and 1B. These devices 7 can be assembled into the composite device 45 that has multiple layers, each including transverse wires arrays and a data layer between the wire arrays.

FIG. 2B shows a cross sectional view taken along line II-II of the stack 45 of the permanent solid state devices 7 of FIG. 2A in an assembled state. In the example of FIG. 2B, each of the permanent solid state memory devices 7 that make up the composite device or stack 45 includes a first substrate 10, a data layer 40, and a second substrate 25. The data layer 40 is sandwiched between each respective pair of substrates 10, 25. An adhesive may be used to bond the devices 7 together to form the composite device 45. A thickness 50 of the substrates may be about ten nanometers to about ten micrometers. Another range for the thickness 50 is about ten nanometers to about one hundred nanometers. The thicknesses 50 may be any value in these ranges or outside these ranges. A thickness 55 of the data layer 40 may be in a range from about three nm to about three hundred nanometers. The thicknesses of the data layers 40 may be any value in this range or outside these ranges.

FIG. 2C shows a cross sectional view taken along line II-II of the stack 45 of the permanent solid state devices of FIG. 2A in an assembled state in accordance with another embodiment. In this embodiment, the first substrates 10 inside the stack 45 may have wire arrays 30 on respective lower surfaces 60 of the first substrates 10. The wire arrays 30 have wires that are oriented transverse to the wires of wire arrays 15 that are supported on the upper surfaces of the first substrates 10. In this way, the intermediate substrates 10 support the second wire arrays 30 as well as the first wire arrays 15, above and below each data layers 40. The stack 45, in this case, is built up by increments 65 that include a first substrate 10 and a data layer 40. The data layers 40 are adjacent to a wire array on the next superjacent first substrate 10 except for the uppermost data layer 40, which may be capped by a second substrate 25 (shown in dashed lines) similar to the second substrates 25 having the wire arrays 30 illustrated in FIGS. 1A and 1B. The stack 45 may be assembled in any manner and may include any number and combination of substrates and data layers that provides the first wire array 15, the data layer 40, and the second wire array 30 with wires transverse to the wires in the first wire array, in that order. Any number of devices may be stacked to provide the composite device or stack 45. The wires in the first wire array 15 may be generally perpendicular to wires in the second wire array 30, as shown in FIGS. 1A-1B. Alternatively, the wires in the first wire array 15 and the wires in the second wire array 30 may extend at any angle relative to each other while lying in generally parallel planes defined by the upper and lower surfaces of the substrates 10, 25.

Thus, the composite device 45 that is shown in FIGS. 2A-2C is an example of three-dimensional storage. Alternatively, another example of three-dimensional storage would be a single solid state device that includes multiple data layers. Because each data layer could extremely thin (e.g., 1 μm), such a solid state device could have many (e.g., 10 to 100, or possibly more) layers of storage. Thus, the density of storage in such a device could be many times greater than known solid state devices, which use only one layer.

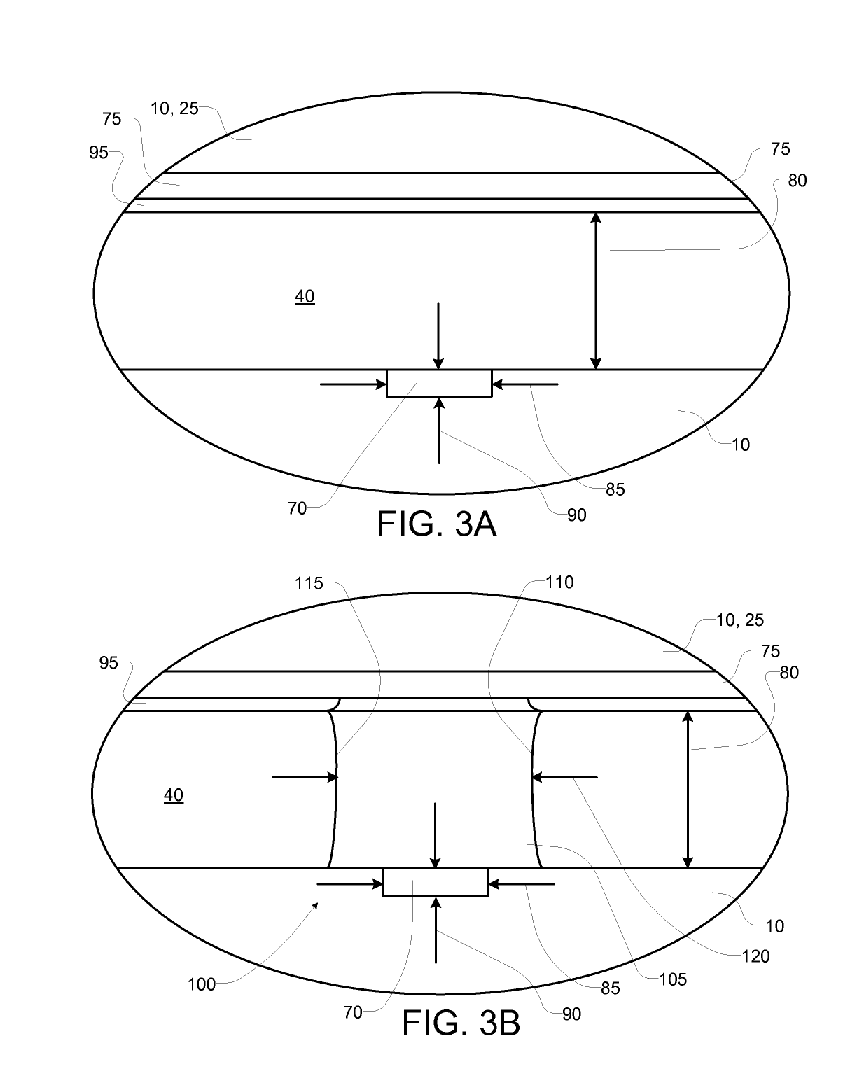

FIG. 3A shows a detailed cross sectional view of a portion of the composite device 45 taken along line III-III in FIG. 1B. This detailed sectional view illustrates a data mark location in the data layer 40 between a first wire 70 supported on the first substrate 10 and a second wire 75 transverse to the first wire 70 and supported on the second substrate 25 prior to writing. Alternatively, the second wire 75 may be supported on the lower surface 60 of another first substrate 10, as described with regard to FIG. 2C. As shown, the first wire 70 extends lengthwise out of the page. The second wire 75 extends side-to-side generally in the plane of the page. When a voltage is applied across these two wires, energy is concentrated in the at least partially conductive data layer 40 in a volume generally between the wires 70, 75. A thickness dimension 80 of the data layer is selected 70 generally provide the space between the first wire array and the second wire array 30, and thus generally the spacing between the first wire 70 and the second wire 75. This spacing may be selected based on the data layer material and the voltages to be applied to the wires 70, 75. A width dimension 85 and a height dimension 90 for the first wire 70 and the second wire 75 are selected to provide the needed capacity for voltages to be applied and the currents to be carried by the first wire 70 and the second wire 75. The material of the wires 70, 75 can be selected from among aluminum, copper, silver, gold, other metals, and combinations thereof without limitation. The first substrate 10 or the second substrate 25 with the second wire array 30 supported thereon may be bonded to the data layer 40 by an adhesive 95, as illustrated.

FIG. 3B shows a detailed cross sectional view taken along line III-III in FIG. 1B illustrating a data mark 100. The data mark includes a void 105 in the data layer 40 between the first wire 70 supported on a first substrate 10 and the second wire 75 that extends transverse to the first wire 70 and is supported on a second substrate 25 after writing. The second substrate 25 may be replaced by a first substrate 10 having a second wire array supported on a lower surface 60, as described with regard to FIG. 2C. As shown, the void 105 is formed when opposing inner walls 110, 115 recede away from each other. The created void 105 may have a width dimension 120.

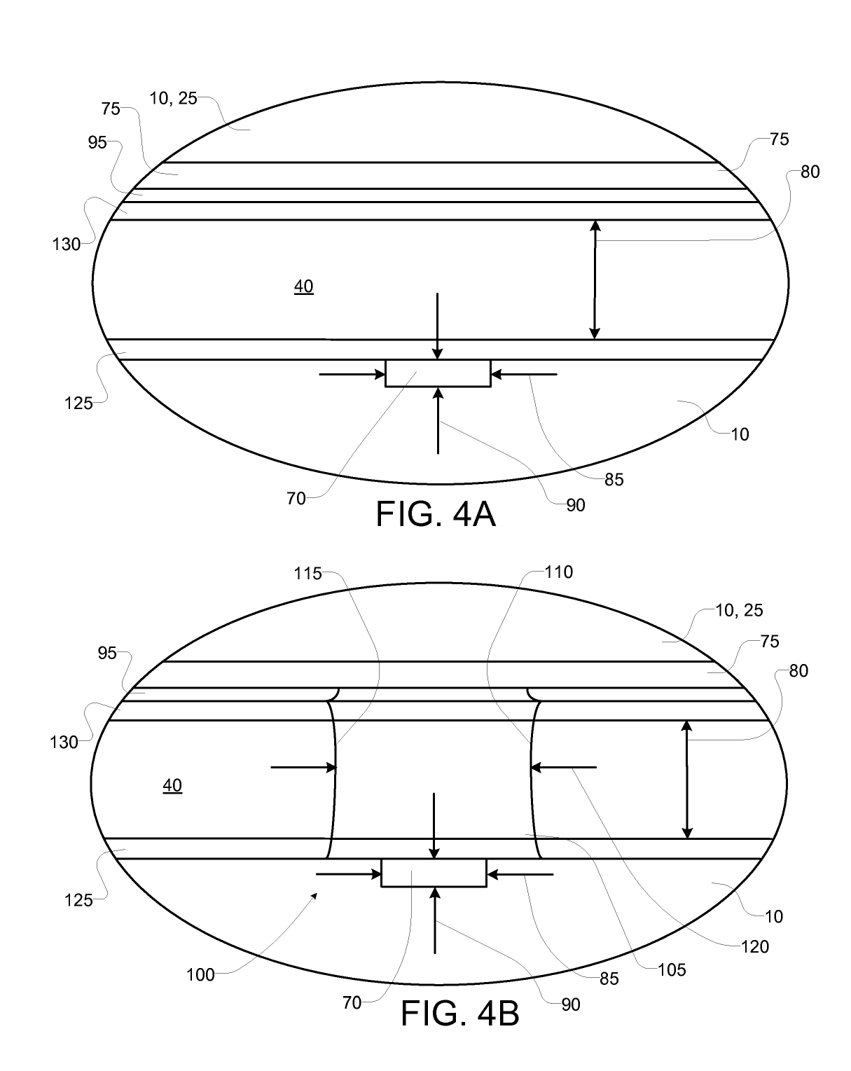

Similar to FIG. 3A, FIG. 4A shows a detailed cross sectional view taken along line III-III in FIG. 1B for a different embodiment that includes carbon coatings 125, 130 on the data layer 40. in this embodiment, the data mark location is in the carbon coated data layer 40 between a first wire 70 supported on the first substrate 10 and a second wire 75 transverse to the first wire 70 and supported on the second substrate 25 prior to writing. As alternatively described, the second wires 75 may be supported on an underside of a next superjacent first substrate 10. The first carbon coating or layer 125 is disposed on the first substrate 10 and first wires 70. The first carbon coating or layer 125 may be in facial contact with the first wires 70 on an underside of the first carbon layer 125. The first carbon coating or layer 125 may also be in facial contact with the data layer 40 on a top side of the first carbon layer 125. A second carbon coating or carbon layer 130 may be placed atop the data layer 40 such that the second carbon layer 130 is in facial contact with the data layer on an underside of the second carbon layer. The second carbon layer 130 may receive the second wires 75 and the second substrate 25 in overlying relation. An intervening layer of adhesive 95 may bond the second carbon layer 130 to the second wires 75 and the second substrate 25. Other variations are also possible. For example, the adhesive layer 95 could be placed between the second carbon layer 130 and the adhesive layer 40 or between any two layers without limitation. Furthermore, the second substrate 25 could be replaced by a next superjacent first substrate 10, as described in alternative configurations. Since carbon is a conductor, the first carbon layer 125 and second carbon layer 130 may act as conductor for current traveling between the first wires 70 and the data layer 40, and the second wires 75 and the data layer 40. Depending on the data layer material, the carbon layers 125, 130 or other generally conductive coupling layers may be incorporated. Such carbon layers 125, 130 or other coupling layers may facilitate de-wetting and thus promote void formation.

Similar to FIG. 3B, FIG. 4B shows a post write detailed cross sectional view taken along line III-III in FIG. 1B for the stack of layers shown in the embodiment of FIG. 4A. Thus, the embodiment of FIG. 4B illustrates a data mark 100 comprising a void 105 in the carbon coated data layer 40 between the first wire 70 supported on the first substrate 10 and the second wire 75 transverse to the first wire 70 and supported on the second substrate 25 after writing. It is to be understood that the second wires 75 may alternatively be supported on an underside of a next superjacent first substrate 10. The first carbon layer 125 and the second carbon layer may help the data layer material to recede during writing when a heating current is passed through the data layer 40 via the first wires 70 and the second wires 75.

The data storage mechanism described herein is substantially different from existing technologies for non-volatile memory, including flash memory, UVEPROM, EEPROM, EPROM and PROM. All of these technologies store data as a charge on a floating gate, or as a fuse which has been blown. An electromagnetic pulse (EMP) event would destroy all of the devices that store data on existing non-volatile memory. Advantageously, however, an EMP event should have essentially no effect on a permanent solid state memory device made in accordance with the present disclosure. Although control elements in a system configured to read from and write to the permanent solid state memory device would not be immune to an EMP event, the control elements could be EMP hardened in accordance with radiation-hardening techniques.

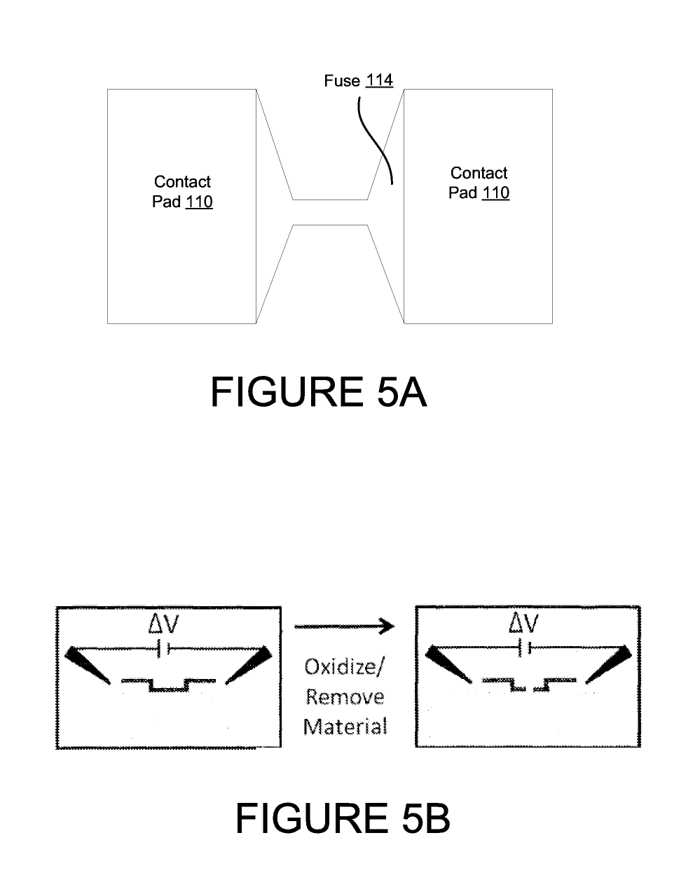

Referring now to FIG. 5A, a drawing of a fuse 114 is shown. The fuse 114 may be positioned between two contacts pads 110. The fuse 114 may be formed between the two wires, in the manner outlined above. As will be appreciated by those skilled in the art, the fuse 114 may be part of the data layer (shown above) and may be “blown” in order to store data. FIG. 5B shows a cross section of the fuse 114 before and after the fuse 114 has been oxidized. More specifically, the left side drawing of FIG. 5B shows the fuse 114 that has not been “blown” (e.g., so that it is given a value of “1” at the fuse location), whereas the right side drawing shows the fuse being blown (e.g., so that it is given a value of “0” at the fuse location). The advantages of carbon include: when it oxidizes, it is completely vaporized and none of it can remain to form dendrites; and it is believed that carbon molecules are very well bonded in all the allotropes, which means they do not move sufficiently to form dendrites.

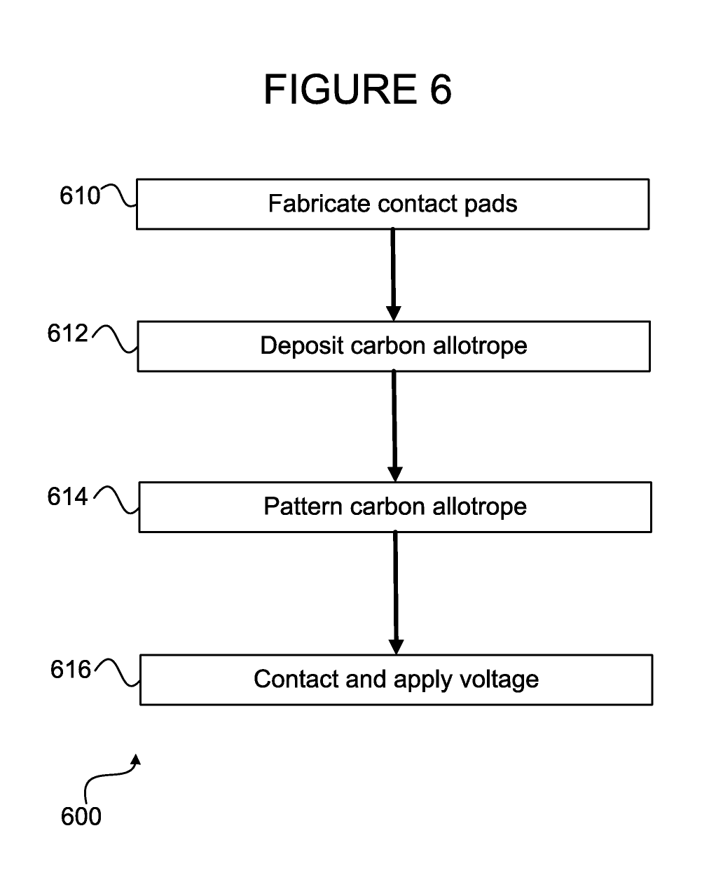

Referring now to FIG. 6, a method 600 of forming the fuse is illustrated. Specifically, the contact pads (such as pads 110) may be fabricated 610. Once fabricated, the carbon allotrope may be deposited 612 on or between the pads (in the manner outlined herein). Once deposited, the carbon allotrope may be patterned 614 such as, for example, so that it has the overall profile shown in FIG. 5A. Once it has been patterned, it may be contacted by wires and receive an applied voltage 616. As described herein, this application of the voltage quickly oxidizes (burns) the carbon, leaving a complete gap where the fuse once was, and thus programming a 0 in that location. If the carbon is not oxidized, a 1 is programmed at that location.

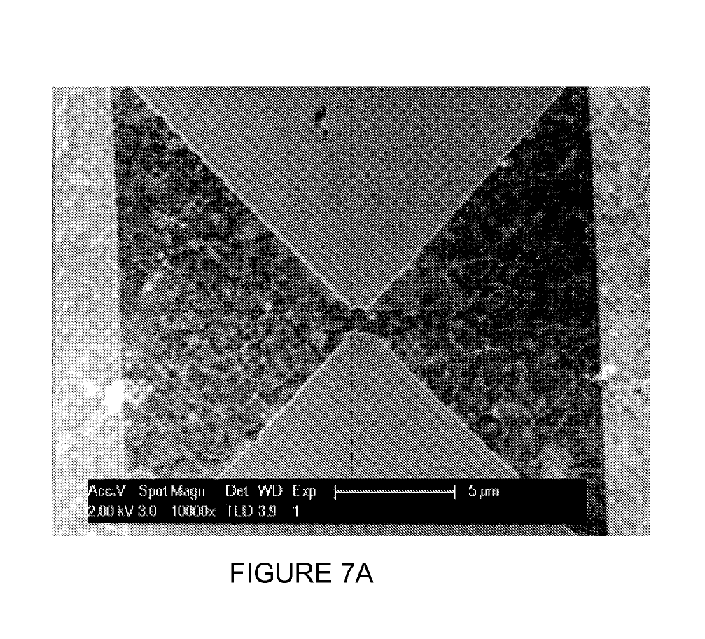

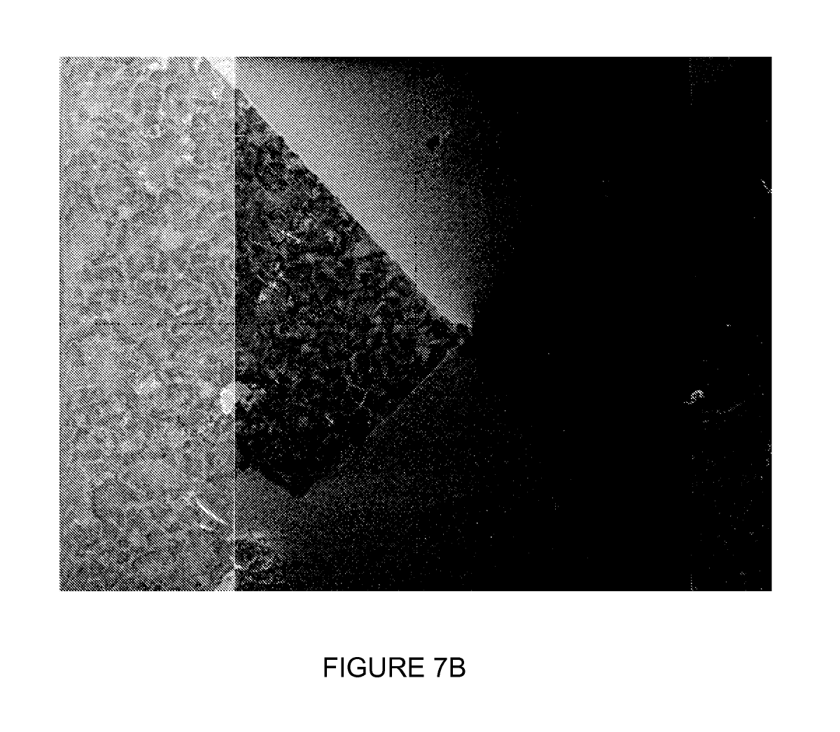

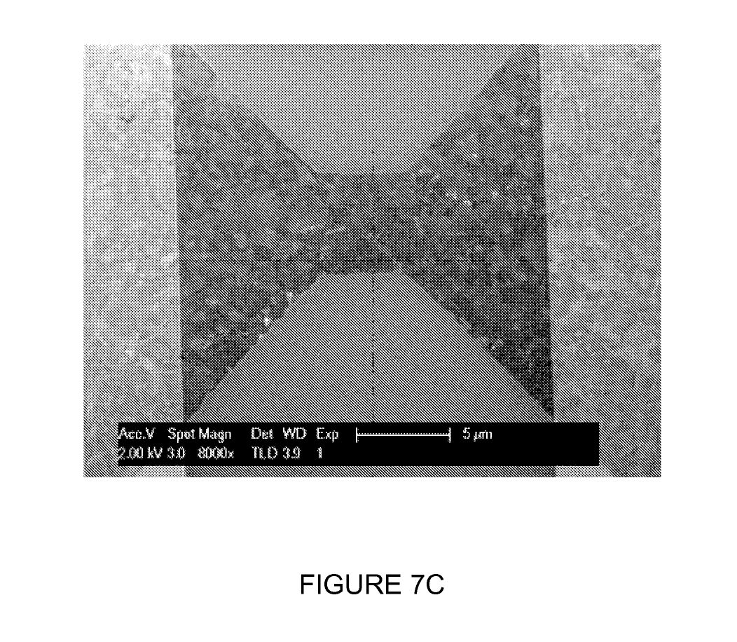

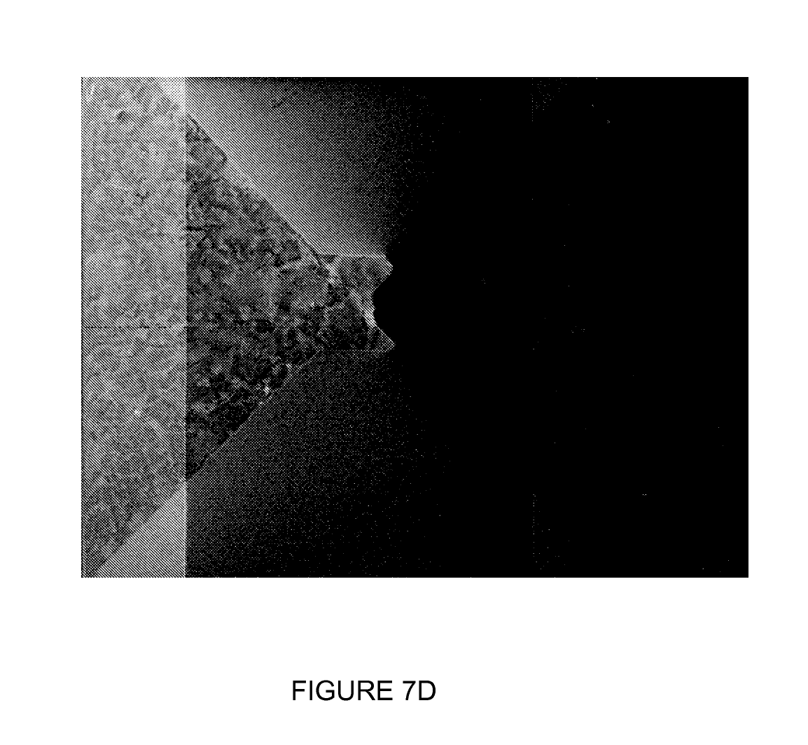

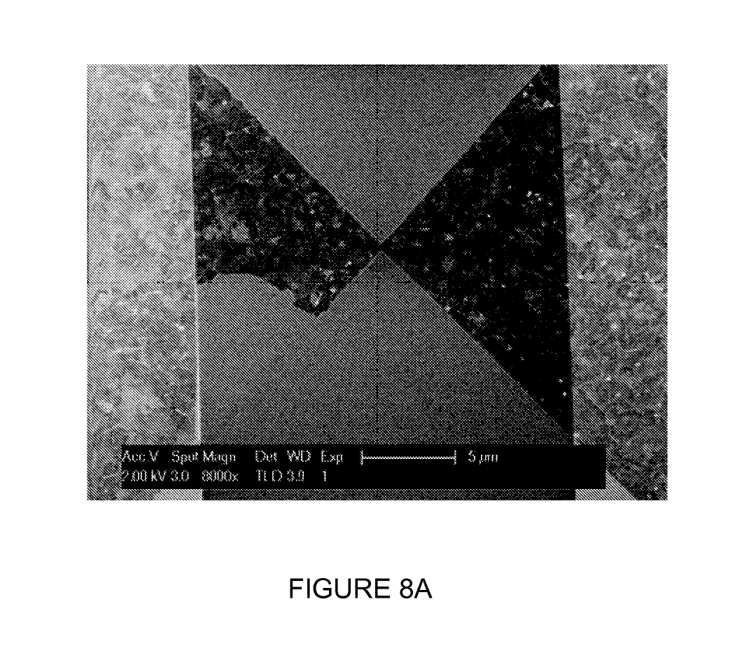

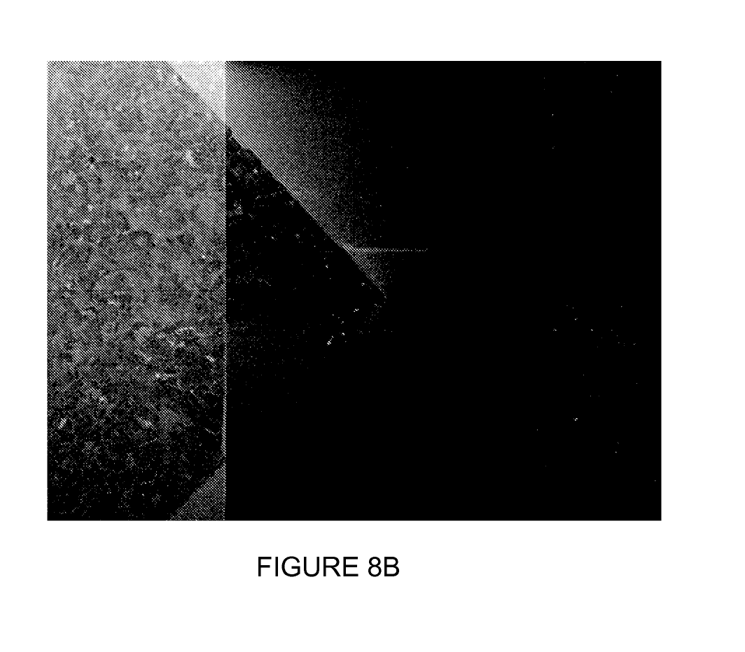

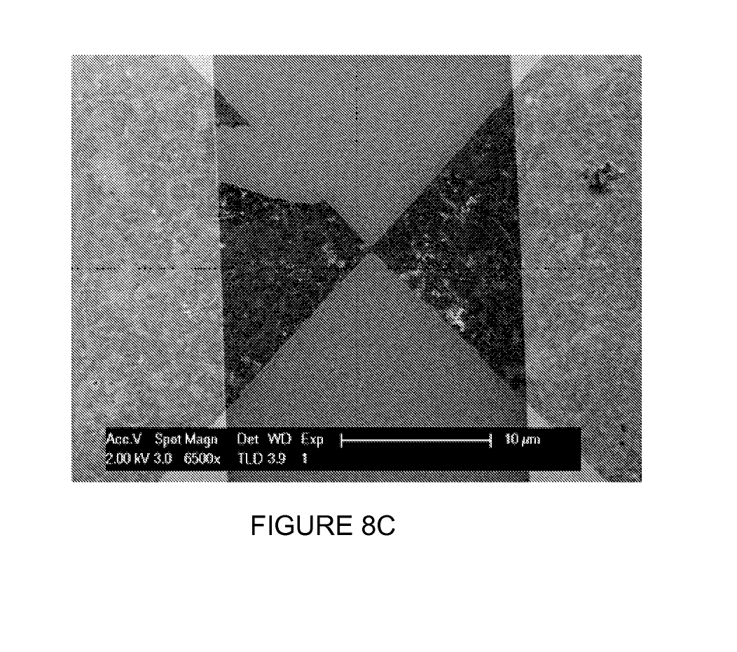

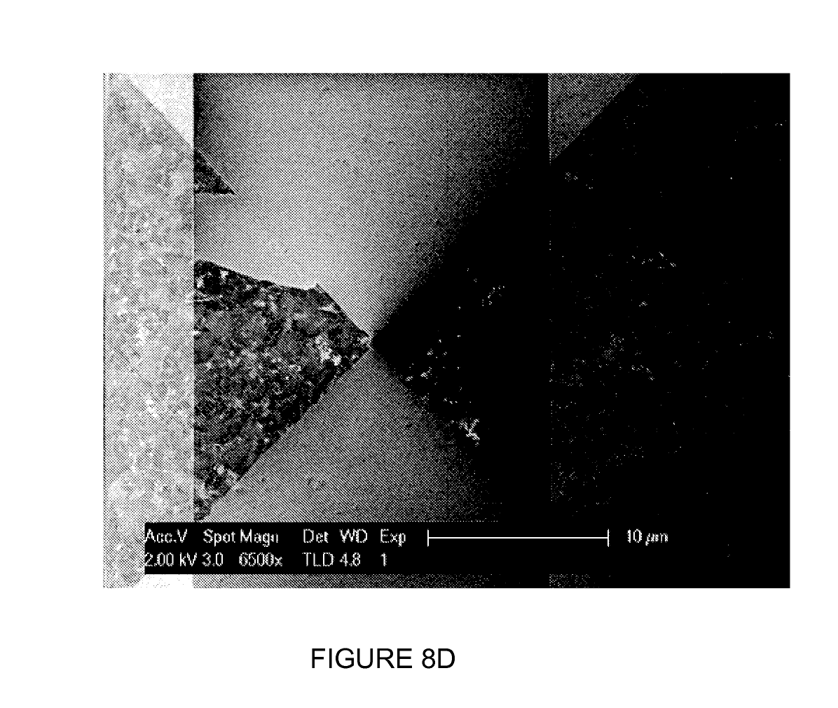

FIGS. 7A-8D show examples of fuses which were programmed through application of a sufficiently high voltage. FIGS. 7A-7D are scanning electron microscope images of fuse devices of different sizes. FIGS. 7A and 7B are images of a fuse that is 1 micron in width at the narrowest point. FIGS. 7C and 7D are images of a fuse that is 5 microns in width at the narrowest point. FIGS. 7A and 7C show the fuses before they were programmed while FIGS. 7B and 7D show the fuses following programming. The applied voltage was ramped up and the current monitored during programming. Samples shown in FIGS. 7B and 7D required 12 and 30 V respectively before the current dropped below the measurement limit of our ammeter. The contrast difference in the left and right sides of the fuses in FIGS. 7B and 7D is a result of charging of one side of the fuses with the electron beam. The high contrast indicates that these fuses are in fact electrically disconnected across the fuse regions.

FIGS. 8A-8D are scanning electron microscope images of fuses which are 500 nm at their narrowest point. FIGS. 8A-8B show a fuse which was programmed at 10 V. FIGS. 8C-8D show a fuse programmed at 20 V. It can be seen that the gap created was larger in FIG. 8D than in FIG. 8B. Thus likely the higher voltage allowed more material to reach temperatures hot enough to cause oxidation and removal of material.

### Methods of Preparation

A simple form of preparing a solid state memory device includes providing at least one first substrate with a first wire array disposed thereon and depositing at least one data material on the first wire array and the first substrate. This embodiment includes providing at least one second substrate with a second wire array disposed thereon and applying the second substrate to the data material such that the data material is between the first wire array and the second wire array. In this embodiment, a first wire in the first wire array and a second wire in the second wire array are configured to apply a voltage of about 1 Volt to about 15 Volts between the first wire and the second wire. Also in this embodiment, the data material is configured to melt and recede away from a data point between the first wire and the second wire when the voltage is applied and the data material is heated by a resulting current to a melting temperature of about 150° C. to about 1500° C. In one embodiment, the data material is configured to melt and recede away from the data point when the data material is heated to a melting temperature of about 600° C. to about 700° C. If tungsten or other metals/alloys/metallic oxides are used as the data material, higher temperatures may be needed in order to melt the material. Those skilled in the art will appreciate the temperatures that need to be achieved in order to melt the metal/alloy/oxide so that the gap is formed.

Embodiments of preparing a solid state memory device include depositing wire arrays on the substrates on surfaces configured to sandwich the data layer between the wire arrays with the wires in one wire array extending transverse to the wires in the other wire array. The materials of the data layer may include at least one of the following allotropes of carbon: single-wall nanotubes, multi-wall nanotubes, graphene (single sheet or multiple sheets), sputtered carbon, amorphous carbon, glassy carbon, or graphitic carbon. As deposited, the carbon allotrope has sufficient conductivity to program a 1 (an intact fuse). When sufficient current is passed through the carbon allotrope, the carbon is quickly oxidized (burned), leaving a complete gap where the fuse once was, and thus programming a 0 in that location. The method of preparing the permanent solid state memory device may include depositing one of these materials or any other material listed herein. Other embodiments may have metals, metal oxides and alloys as the data layer and may be formed using the methods described herein and in the '285 publication.

Deposition of the wire arrays may include one or more steps from among sputtering, evaporation, chemical vapor deposition, pulsed laser deposition, and molecular beam epitaxy. A continuous layer may be applied to a substrate surface that includes grooves patterned in a configuration corresponding to the desired wire array. Then, substantially all of the continuous layer except for the material that was deposited in the grooves may be removed. In this way, the wire arrays remain on the substrate in the patterned grooves.

The step of depositing the data material may include depositing the data material by one of sputtering, evaporation, chemical vapor deposition, pulsed laser deposition, and molecular beam epitaxy to a thickness of about 2 nm to about 300 nm on the first substrate. Thicknesses outside this range or within this range may be deposited. In one example, the depositing step includes depositing the data layer material to a thickness of about 15 nm. Providing the first substrate may include depositing the first wire array on the first substrate. Providing the second substrate may include depositing the second wire array on the second substrate. The second substrate or another first substrate having the second wire array on its lower surface may be bonded to the data layer by an adhesive.

In one embodiment, the method includes placing a carbon or other material coupling layer as an intervening layer between the data layer and the wire arrays. Placing the coupling layer may comprise any of the deposition steps described for depositing the data layer. The coupling layer(s) may be deposited on the first substrate and the first wire array, the second substrate and the second wire array, and/or on either face of the data layer without limitation.

Additional embodiments of the invention are directed towards methods of preparing a system for reading and/or writing data to a permanent solid state memory device. As such, the methods of preparing may include assembling various control elements including transistors, drivers, amplifiers, row and column sense amplifiers, etc. that function to select and apply voltages to the wires in the wire arrays in the proper sequence for writing to and/or reading digital data from the permanent solid state memory device. These elements and the resulting system may include conventional elements and combinations and/or elements and combinations that have not yet been developed without limitation.

### Methods of Use

In a simple form, using a solid state memory device includes providing at least one first layer with a first wire array disposed therein, and providing at least one second layer with a second wire array disposed therein. Using the solid state memory device also includes applying a voltage across a first wire of a first wire array in a first layer and a second wire of a second wire array in a second layer. In this embodiment, using the solid state memory device includes heating a data layer between the first layer and the second layer by the applying step. This embodiment includes melting a data layer material in the data layer and causing the data layer material to recede from a location between the first wire and the second wire. Melting in this manner forms receded walls and a data point comprising a void within the receded walls of the data layer material.

In one embodiment, the melting step comprises creating a data point including a void between the receded walls of data material in which the walls are spaced about 30 nm to about 5000 nm from each other on opposite sides of the data point.

In accordance with some embodiments, the applying step includes applying a voltage of about 1 Volt to about 15 Volts. In other embodiments, the applying step includes applying a voltage of about 2.5 Volts to about 6 Volts. Applying a voltage in this way creates a current through the data layer, which is somewhat resistive and therefore undergoes resistive heating. Some embodiments include thus resistively heating a portion of the data layer to a temperature of about 150° C. to about 1500° C. Other embodiments, include heating a portion of the data layer to a temperature of about 600° C. to about 700° C. Again, higher temperatures may be required if the data layer is a metal, oxide or alloy, and heating to those higher temperatures is also within the scope of the present embodiments.

In one embodiment of the present invention, the method includes using a computer that is operably connected to the various control elements including transistors, drivers, amplifiers, row and column sense amplifiers, etc. that function to select and apply voltages to the wires in the wire arrays in the proper sequence for writing and/or reading. When reading the data, one conductivity through the data layer at the data point exists before the void forms and a different conductivity is created and exists after the void forms. One of the advantages of the permanent solid state memory device is that it enables very high data densities. Also, the readout may be parallel and very fast.

A write strategy may be provided in the control elements for adjusting the voltages and resulting currents through the data layer during writing. Voltages may be varied to provide the energy that is needed while protecting the data layer and other nearby elements of the permanent solid state memory device during recording of data. For example, higher voltages and currents may be needed at the beginning of writing a data point while lower voltages and currents may be needed as the void of the data point begins to form. In one example, modulation of the voltage/current may be provided under electronic control using a computer, software, and/or firmware in order to avoid overheating at the data points.

The '285 publication discloses that metal and metallic-oxide materials may be used for the fuse. Specifically, this publication discloses that metals/materials such as tellurium, selenium, and other metals/metal alloys can be used as fuse materials. In the process of programming the data into these fuses, the metal or metal alloy is heated quickly, causing the material to move away and a gap to form. This gap permanently changes the resistance of the fuse, thus programming the data. Where a fuse is intact, a 1 is stored; where it has been destroyed, a 0 is stored (or vice versa).

However, in other embodiments, a metal, a metal alloy, a metal oxide, or successive layers of these materials may be used as the fuse material(s). These metallic and metallic-oxide materials may include materials such as tungsten (W), Rhenium (Rh), Osmium (Os), Iridium (Ir),

Molybdenum (Mo), Ruthenium (Ru), Rhodium (Rh), Chromium (Cr), and Manganese (Mn), and/or oxides of these metals and/or alloys of these metals.

As deposited, the fuse material(s) may be sufficiently conductive to create a 1 (an intact fuse). When current is passed through the fuse, the temperature of the fuse material(s) may be increased dramatically and quickly, which more completely oxidizes the fuse material(s) and thus dramatically changes the resistivity of the fuse material(s) but does not destroy the fuse material(s). This change in the resistivity of the fuse material(s) creates a programmed 0 in that location.

The method of fabrication of these thin film structures and devices could include sputtering of the metal. A stack could be produced by methods including sputtering or alternating layers of metal and metal oxide (or other methods described herein and in the '285 publication).

The advantages of the methods and materials disclosed herein may include the following. The metals, metal alloys, or metal oxides of the type described herein, or successive layers thereof, are materials that have extremely low mobility and thus do not permit dendrites to form. The programming method of increasing the resistivity of the fuse without destroying the fuse is fundamentally non-destructive in nature, and thus much less likely to produce material from which future failures could be created. Both the original fuse material and the highly resistive programmed fuse material are extremely stable, and will endure for centuries.

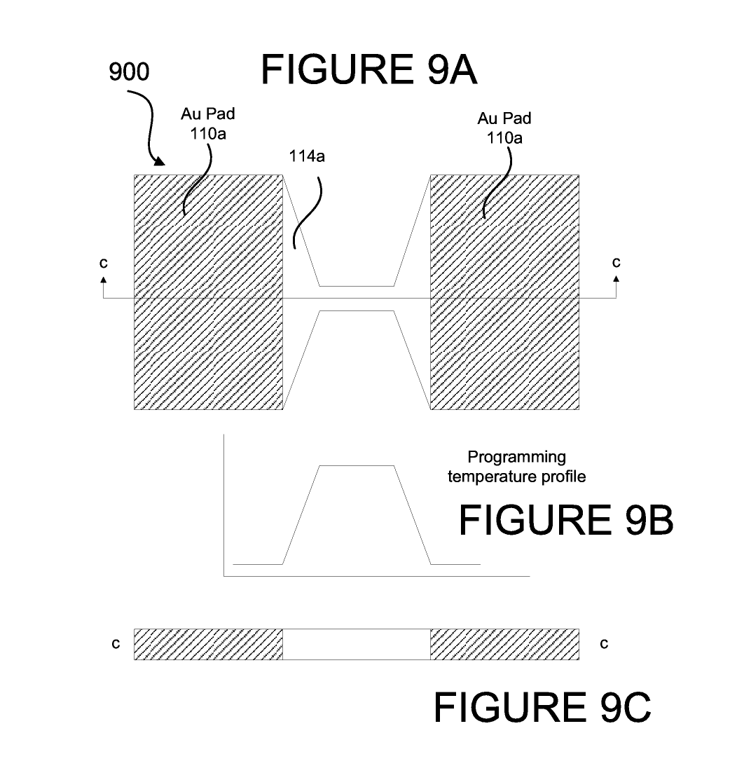

FIGS. 9A-9C illustrate another embodiment of a fuse 900 which is positioned between two contact pads 110a. In the depicted embodiment, these pads 110a are made of gold (Au), but other materials may also be used. As shown in FIG. 9A, the fuse 114a, which is shaped like a bowtie as viewed from the top, is made of a metal, metal alloy or metal oxide. The metallic materials for the fuse 114a may comprise tungsten (W), Rhenium (Rh), Osmium (Os), Iridium (Ir), Molybdenum (Mo), Ruthenium (Ru), Rhodium (Rh), Chromium (Cr), and Manganese (Mn), and/or oxides of these metals and/or alloys of these metals. FIG. 9B shows a graph of the programming temperature necessary to create a void within the fuse (and thus program the fuse). As shown by FIG. 9B, the temperature rises as the metal of the bowtie region is fused. Finally, FIG. 9C, which is a sectional view taken along the line C-C of FIG. 9A, shows the various layers of metal or metal oxide between the pads 110a. When sufficient current is applied, the “neck region of the bowtie” (e.g., the region of smallest diameter) is fully oxidized, while other parts of the fuse material may remain. As shown in FIG. 9A, the fuse 114a may be structured as a bowtie. While the fuse 114a is made of metal, it should be noted that fuses made of carbon allotropes may also be shaped as a bowtie as well. The fuse 114a (which may be the data layer of the storage structure), comprises a neck region 116 that is positioned between two side regions 118, thereby forming a “bowtie.” Thus, in some embodiments, the neck 116 may be fully oxidized (or fully burned) while the side regions 118 are only partially oxidized (burned).

All of the compositions and/or methods and/or processes and/or apparatus disclosed and claimed herein can be made and executed without undue experimentation in light of the present disclosure. While the compositions and methods of this invention have been described in terms of preferred embodiments, it will be apparent to those of skill in the art that variations may be applied to the compositions and/or methods and/or apparatus and/or processes and in the steps or in the sequence of steps of the methods described herein without departing from the concept and scope of the invention. More specifically, it will be apparent that certain agents which are both chemically and physically related may be substituted for the agents described herein while the same or similar results would be achieved. All such similar substitutes and modifications apparent to those skilled in the art are deemed to be within the scope and concept of the invention.

1. A solid state memory device, comprising:
at least one first array of wires in a first layer;
at least one second array of wires extending transverse to the first array of wires in a second layer that is generally parallel to the first layer; and
at least one data layer disposed between the first layer and the second layer such that a voltage applied to a first wire in the first array and to a second wire in the second array heats the data layer at a location between the first wire and the second wire and forms a data point comprising a void when data is written to the solid state memory device,
wherein the data layer is an allotrope of carbon or a metal, a metal alloy, or a metallic oxide comprising one or more of the following metals: Tungsten (W), Rhenium (Rh), Osmium (Os), Iridium (Ir), Molybdenum (Mo), Ruthenium (Ru), Rhodium (Rh), Chromium (Cr), and Manganese (Mn).

2. The solid state memory device of claim 1, wherein the data layer is an allotrope of carbon selected from the group consisting of single-wall nanotubes, multi-wall nanotubes, graphene, multi-layer graphene, sputtered carbon, amorphous carbon, glassy carbon, and graphitic carbon.

3. The solid state memory device of claim 1, wherein the data layer has a thickness of about 3 nm to about 300 nm.

4. The solid state memory device of claim 1, wherein the first wire and the second wire have a maximum dimension taken along a cross-section generally perpendicular to a lengthwise extension of the wire of about 3 nm to about 500 nm.

5. The solid state memory device of claim 1, wherein the first wire and the second wire have a cross sectional area generally perpendicular to a lengthwise extension of the wires of about 900 nm² to about 25,000,000 nm².

6. The solid state memory device of claim 1, wherein:
the first layer comprises a first substrate and the first wire array supported on the first substrate;
the second layer comprises a second substrate and the second wire array supported on the second substrate; and
the first substrate is bonded to the second substrate with the data layer disposed between the first substrate and the second substrate.

7. The solid state memory device of claim 1, further comprising:
a first intervening coupling layer between the first array of wires and the data layer; and
a second intervening coupling layer between the second array of wires and the data layer.

8. The solid state memory device of claim 1, further comprising:
multiple data layers and multiple wire arrays disposed on opposing sides of the multiple data layers, wherein the multiple data layers are in respective layers between respective wire arrays.

9. The solid state memory device of claim 1, wherein the solid state memory device is immune to an electromagnetic pulse event.

10. A method for preparing a solid state memory device, the method comprising:
providing at least one first substrate with a first wire array disposed thereon;
depositing at least one data material on the first substrate;
providing at least one second substrate with a second wire array disposed thereon; and
applying the second substrate to the data material such that the data material is between the first wire array and the second wire array;
wherein:
a first wire in the first wire array and a second wire in the second wire array are configured to apply a voltage of about 1 Volt to about 15 Volts between the first wire and the second wire; and
the data material is an allotrope of carbon or a metal, a metal alloy or a metallic oxide comprising one or more of the following metals: Tungsten (W), Rhenium (Rh), Osmium (Os), Iridium (Ir), Molybdenum (Mo), Ruthenium (Ru), Rhodium (Rh), Chromium (Cr), and Manganese (Mn).

11. The method of claim 10, wherein if the data material is an allotrope of carbon, the data material oxidizes between the first wire and the second wire when the voltage is applied.

12. The method of claim 10, wherein if the data material is a metal or a metallic oxide, the data material melts and recedes away from a data point between the first wire and the second wire when the voltage is applied.

13. The method of claim 10, wherein depositing the data material comprises depositing the data material to a thickness of about 3 nm to about 300 nm on the first substrate.

14. The method of claim 10, wherein providing the at least one first substrate comprises depositing the first wire array on the first substrate.

15. The method of claim 10, wherein providing the at least one second substrate comprises depositing the second wire array on the second substrate.

16. The method of claim 10, further comprising:
applying a first coupling layer between the first wire array and the first substrate; and
applying a second coupling layer between the second wire array and the second substrate.

17. A method of using a solid state memory device, the method comprising:
providing at least one first layer with a first wire array disposed therein;
providing at least one second layer with a second wire array disposed therein;
applying a voltage across a first wire of a first wire array in a first layer and a second wire of a second wire array in a second layer;
heating a data layer between the first layer and the second layer by the applying step; and
melting a data layer material in the data layer and forming a data point comprising a void in the data layer material;
wherein the data material is an allotrope of carbon or a metal, a metal alloy or a metallic oxide comprising one or more of the following metals: Tungsten (W), Rhenium (Rh), Osmium (Os), Iridium (Ir), Molybdenum (Mo), Ruthenium (Ru), Rhodium (Rh), Chromium (Cr), and Manganese (Mn).

18. The method of claim 17, wherein the melting step comprises causing the data layer material to recede from a location between the first wire and the second wire, forming receded walls and the void within the receded walls in the data layer material.

19. A solid state memory device, comprising:
at least one first array of wires;
at least one second array of wires; and
at least one data layer disposed between the first array of wires and the second array of wires such that a voltage applied to a first wire in the first array of wires and to a second wire in the second array of wires heats the data layer at a location between the first wire and the second wire and forms a data point comprising a void when data is written to the solid state memory device,
wherein the data layer is an allotrope of carbon that is at least partially oxidized when the voltage is applied.

20. The solid state memory device of claim 19, wherein the data layer is in a bowtie structure.
